(19) United States
(12) Patent Application Publication
(10) Pub. No.: US 2025/0079128 A1
(43) Pub. Date: Mar. 6, 2025

(54) PROCESSING SUBSTRATES WITH PLASMA MODULATED BY DC MAGNETIC FIELDS

(71) Applicant: Tokyo Electron Limited, Tokyo (JP)

(72) Inventors: Ya-Ming Chen, Austin, TX (US); Shyam Sridhar, Austin, TX (US); Peter Lowell George Ventzek, Austin, TX (US); Mitsunori Ohata, Taiwa-cho (JP)

(21) Appl. No.: 18/241,008

(22) Filed: Aug. 31, 2023

(51) Int. Cl. H01J 37/32

(52) U.S. Cl. CPC H01J 37/32449; H01J 37/32174; H01J 37/3266; H01J 37/32715; H01J 37/32954; H01J 2237/327

(57) ABSTRACT

A method for plasma processing a substrate, where the method includes generating a plasma in a plasma chamber within which the substrate is held during processing, where generating the plasma includes: flowing a discharge gas through the plasma chamber; coupling a radio frequency (RF) source signal to a first RF electrode, where the coupling ionizes the discharge gas; and coupling a bias signal to a second RF electrode, the bias signal being a periodic series of bias pulses, each period having a bias-ON time and a bias-OFF time, where a bias voltage waveform is applied during the bias-ON time; generating a pulsed DC magnetic field in the plasma chamber, by coupling a magnetizing signal to an electromagnet, the magnetizing signal being a periodic series of current pulses; and prior to coupling the magnetizing signal, synchronizing the periodic series of current pulses with the bias signal to flow a DC magnetizing current during the bias-ON time.

### TECHNICAL FIELD

The present invention relates generally to plasma processing techniques, and, in particular embodiments, to systems and methods for processing substrates with plasma modulated by DC magnetic fields.

### BACKGROUND

An integrated circuit (IC) is a monolithic structure comprising a network of electronic components in a semiconductor substrate. An array of IC units is formed on each substrate as a batch of substrates gets processed through a series of patterning levels. At each level, a patterned layer of various materials are formed using deposition, photolithography, and etch processes. Typically, a minimum half-pitch of an array of trenches or holes fabricated at a patterning level defines its patterning capability. About every two years, a new IC node is introduced having more advanced technology that enables doubling the component density to reduce cost per unit and, concurrently, enhance performance and functionality. The doubling results from shrinking minimum feature sizes and deploying three dimensional (3D) devices, a combination that requires fabricating high aspect ratio structures with controlled low dimensional variations.

A first step in patterning a layer is printing, in which a pattern of actinic radiation is transferred to a photoresist layer coated on the substrate. In a patterning process, referred to as single patterning, printing is followed by etching to transfer the resist pattern to an optional hard mask and thence to a target layer. The patterning capability of single patterning is the resolution limit of the optics, which is proportional to λ/NA, where λ is the radiation wavelength and NA is numerical aperture. The minimum half-pitch was reduced from 1 micron to 0.1 micron in two decades, during which λ was reduced from 436 nm (ultraviolet (UV) mercury lamp) to 193 nm (deep-UV (DUV) ArF excimer laser). A shorter λ=13.5 nm (extreme UV (EUV) tin plasma) lithography system took almost another two decades to develop. In the interim, scaling was enabled by using techniques such as optical proximity correction (OPC), phase shift photomask, immersion lithography (193-i), and multiple patterning, but at a higher processing cost and new patterning errors such as pitch walking. Recently, 13.5 nm EUV is being used for cost-effective manufacturing at the sub-10 nm nodes, where lateral features less than 20 nm appear frequently in IC designs, thus pushing the aspect ratios of the respective vertical structures to a range requiring special etch processes, generally referred to as high aspect ratio contact (HARC) etch.

Many of the deposition and etch steps in forming 3D devices (e.g., nanosheet transistors and vertical NAND (V-NAND) memory) are plasma processes, some of which, such as the HARC etch, may need special plasma properties to provide, for example, a highly collimated ion flux to the substrate. Further innovations are desired to gain enhanced control over plasma properties such as plasma density, electron temperature, radical flux, ion flux, and ion angle and energy distributions to meet the challenge of patterning high aspect ratio features at a nanoscale pitch with high-yield for volume manufacturing.

### SUMMARY

A method for plasma processing a substrate, where the method includes generating a plasma in a plasma chamber within which the substrate is held during processing, where generating the plasma includes: flowing a discharge gas through the plasma chamber; coupling a radio frequency (RF) source signal to a first RF electrode, where the coupling ionizes the discharge gas; and coupling a bias signal to a second RF electrode, the bias signal being a periodic series of bias pulses, each period having a bias-ON time and a bias-OFF time, where a bias voltage waveform is applied during the bias-ON time; generating a pulsed DC magnetic field in the plasma chamber, by coupling a magnetizing signal to an electromagnet, the magnetizing signal being a periodic series of current pulses; and prior to coupling the magnetizing signal, synchronizing the periodic series of current pulses with the bias signal to flow a DC magnetizing current during the bias-ON time.

A system for plasma processing, where the system includes a plasma chamber; a substrate holder configured to hold a substrate in the plasma chamber; a gas flow system configured to flow a discharge gas through the plasma chamber; a first radio frequency (RF) electrode; a second RF electrode, where the first RF electrode and the second RF electrode are configured to cooperatively generate a plasma in the plasma chamber; an electromagnet configured to generate a pulsed DC magnetic field in the plasma chamber, where the pulsed DC magnetic field is configured to modulate an electron temperature profile of the plasma; a first electrical circuit configured to output an RF source signal; a second electrical circuit configured to output a bias signal; a third electrical circuit configured to output a magnetizing signal; and a controller configured to send control signals to the first, second, and third electrical circuits, to adjust and synchronize the RF source signal, the bias signal, and the magnetizing signal.

A method for plasma processing a substrate, where the method includes flowing a discharge gas through a chamber; coupling a radio frequency (RF) source signal to a first RF electrode; and coupling a bias signal to a second RF electrode, the bias signal being a periodic series of bias pulses, each period being a sum of a bias-ON time and a bias-OFF time, where a bias voltage waveform is applied during the bias-ON time; generating a pulsed DC magnetic field in the chamber, by coupling a magnetizing signal to an electromagnet, the magnetizing signal being a periodic series of current pulses; and prior to coupling the magnetizing signal, synchronizing the periodic series of current pulses with the bias signal to flow a DC magnetizing current during the bias-ON time.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A illustrates a schematic of a plasma processing system, in accordance with some embodiment;

FIG. 1B illustrates a schematic of a plasma processing system, in accordance with some other embodiment;

FIG. 2 is a flowchart summarizing a method for plasma processing a substrate, in accordance with some embodiments;

FIG. 3A illustrates graphs of the waveforms of the source signal, the bias signal, and the magnetizing signal and the temporal response of the average electron temperature in the central region of the plasma chamber in accordance with one embodiment; and

FIG. 3B illustrates graphs of the waveforms of the source signal, the bias signal, and the magnetizing signal and the temporal response of the average electron temperature in the central region of the plasma chamber in accordance with another embodiment.

### DETAILED DESCRIPTION OF ILLUSTRATIVE EMBODIMENTS

This disclosure describes embodiments of methods for processing a substrate with plasma modulated by a pulsed DC magnetic field in a plasma chamber coupled to a gas flow system to flow a discharge gas at a low pressure through the chamber. The plasma may be generated by coupling radio frequency (RF) power to ionize the gas to ignite and sustain a glow discharge plasma, and the pulsed DC magnetic field may be generated by an electromagnet magnetized with pulsed DC current. The electric and magnetic fields in the chamber may be configured to reduce an effective electron temperature (Tₑ) of the plasma in a region of the chamber above the substrate, as explained in further detail below. An effect of reducing Tₑ is to alter ion velocities such that variances of ion angle and ion energy get reduced in a joint distribution of the angle and energy of ions in an ion flux incident on the substrate. Thus, with the embodiments of methods described in this disclosure, a highly collimated flux of ions with precisely controlled kinetic energy may be made available to perform plasma processing.

An ion flux with very small spread in ion angle and energy is advantageous for an anisotropic reactive ion etch (RIE) process, especially when the RIE process is for etching high aspect ratio features, commonly referred to as a high aspect ratio contact (HARC) etch. With lateral dimensions of the electronic components in ICs being scaled more rapidly than vertical dimensions, the aspect ratios of vertical structures, at most patterning levels, are on an upward trend. For example, in the back end of line (BEOL), widths of holes (e.g., for contacts and vias) and trenches (e.g., for metal lines) in interlayer dielectric (ILD) layers have shrunk more than the ILD thicknesses and trench depths. In the front end of line (FEOL), the advent of 3D field-effect transistors (FET) (e.g., FinFET, nanosheet FET, forksheet FET, and complementary FET (CFET)) and 3D memory (e.g., the vertical NAND (V-NAND) memory) has, likewise, led to vertical structures with aspect ratios increasing with miniaturization. Self-aligned quadruple patterning (SAQP) with 193 nm immersion (193-i) lithography was used at the 10 nm node to fabricate features at a minimum half-pitch of about 25 nm. But, IC designs targeting the sub-10 nm nodes include features in several patterning layers, where the minimum half-pitch is less than 20 nm. For these, the more cost effective 13.5 nm EUV single exposure lithography is used to print the pattern.

After printing, the pattern is transferred to a hard mask layer using the resist as an etch mask, and the hard mask layer is used as the etch mask to pattern vertical openings (e.g., via holes) in a target layer (e.g., an ILD layer) using anisotropic RIE processes. For the dimensions at the sub-10 nm nodes, commonly used vertical structures such as contacts and vias may have aspect ratios exceeding 10; and the highest aspect ratios may be in a range of 50 to 100. It is non-trivial to provide a HARC etch for fabricating nanoscale width openings having such high aspect ratios. In addition, in order to achieve high yield and reliability, the process may have to meet stringent specifications for sidewall profile control and local critical dimension uniformity (LCDU). As explained below, to help the HARC etch meet these requirements, the plasma processing equipment and method may need to generate a vertically downward ion flux to the substrate, where the ion distribution is controlled to have very narrow spreads in ion angle and energy. For specificity, a zero degree ion angle is the vertically downward direction of a velocity of an ion when it strikes a major surface of the substrate in a direction normal to the surface.

During HARC etch processing, it is undesirable to have energetic ions colliding with sidewalls exposed by the etching. Such collisions may cause undesired effects such as line edge roughness (LER) and undercut. Furthermore, inelastic collisions and ion absorption at the sidewall may randomly reduce availability of ions with high vertically directed energy at the bottom of a partially etched opening to cause a correspondingly random variation in etch rate. As the bottom of a partially etched feature progresses deeper during anisotropic etching, the aspect ratio of a partially etched feature increases, thus squeezing a tolerance for fluctuation in ion angles around zero degree. Clearly, a reduced spread in the angle distribution provides an advantage for a HARC etch process by reducing the probability of an incoming ion colliding with the sidewall.

Ions within the plasma in the chamber collide with neighboring particles, which are mostly neutral particles. In general, ion angle and kinetic energy are both affected by random collisions. Hence, the variance in ion energy is related to the variance in ion angle. It is noted that, in this disclosure, plasma processing refers to direct plasma processing, so the ion angle and energy of interest are that of ions just prior to striking the surface of the substrate being processed, after accelerating across a plasma sheath that is formed adjacent above the surface of the substrate. The sheath is a narrow positively charged region of high electric field directed toward the surface that forms along the periphery adjacent to a boundary surface, whereas bulk of the glow discharge plasma, referred to as bulk plasma, is a charge-neutral region, (i.e., there is negligible difference between positive and negative charge densities). Between the bulk plasma and the sheath, is a quasi-neutral transition region, referred to as the pre-sheath. The ion velocity distributions in these three regions and the effect of the electron temperature (Tₑ) on the velocity distribution of ions in the ion flux incident on the surface from the sheath are described below.

The glow discharge plasma in the chamber comprises two species of charged particles, ions and free electrons, along with a majority of neutral particles. For simplicity, in the discussions in this disclosure, we lump together all the neutral particles as a single third species, referred to as neutrals. Furthermore, we assume the ions are a single species having one unit of positive electronic charge. These simplifications are for clarity of the description and not to be construed as limiting the scope of the invention.

The particles are distributed over a wide range of energies. The energy distribution of the particles of each species may be approximated by a Maxwellian distribution function, which is proportional to exp (−E/k_{B}T), where, E denotes the total energy (kinetic and potential energy) of a particle, k_{B} is Boltzmann's constant, and T denotes the effective temperature, which represents an average kinetic energy (equal to 3/2 k_{B}T) of a particle of the species. Note that, in the Maxwellian approximation, the kinetic energy is distributed isotropically; hence, the directed component of kinetic energy (directed vertically downwards) is not included in 3/2 k_{B}T. For example, ions in the highly collimated ion flux impinging on the surface have a large directed component of kinetic energy, but an effective ion temperature in the sheath represents only the much smaller random isotropic component of the ion kinetic energy.

The RF power sustaining the glow discharge increases the average kinetic energy of the gaseous mixture in the chamber beyond the thermal equilibrium value given by an ambient temperature. The excess kinetic energy is split unevenly among the three species because of unequal energy absorption and distribution of via collisions. Thus, while in thermal equilibrium, T is equal to an ambient temperature, in non-equilibrium, the steady state may result in unequal effective temperatures for each of the species. The discharge plasma is considered not to be in thermal equilibrium because of a high rate at which electric potential energy from the externally induced RF electric field gets converted to kinetic energy of the free electrons in the plasma. In general, the steady state effective temperature of a species is the net result of the rates at which the particles of that species gain and lose kinetic energy during an initial transient that settles to the steady state of the plasma.

The electrons being extremely light compared to ions (typically, having a mass ratio of several thousand), have extremely high mobility. Due to the high electron mobility, the free electrons acquire kinetic energy at a high rate from the RF electric fields in the bulk plasma (much higher than that for ions). Furthermore, although free electrons collide elastically with the other species (i.e. the heavier ions and neutrals), very little momentum (hence kinetic energy) is transferred, again primarily because of the large mass ratio. With the rate of kinetic energy gained being much larger than the rate of kinetic energy lost, the average kinetic energy of free electrons rapidly rises to a steady state value corresponding to Tₑ of the order of 10,000 K or 1 eV (i.e., roughly 30 to 200 times the thermal equilibrium value). The energetic free electrons cause further ionization by inelastic collisions with neutrals, thus generating the ion-electron pairs that sustain the bulk plasma and the steady state fluxes of ions and free electrons to the boundary surfaces, which include the chamber walls and the major surface of the substrate.

Neutrals, on the other hand, do not absorb energy from electromagnetic (EM) fields. Besides, as mentioned above, collisions of neutrals with high energy free electrons may be inelastic, where, instead of increasing the kinetic energy of the neutrals, kinetic energy is transferred from the free electrons to ionize the neutrals. With negligible increase in their kinetic energy, the effective temperature of the neutrals, remains at the ambient temperature (e.g., about 300 K or 0.026 eV). In contrast, on average, the kinetic energy of ions is increased slightly through collisions with the more energetic electrons, while a fraction of the gain is lost, mostly in collisions with neutrals. The net result is that the effective temperature of the ions (Tᵢ) is slightly higher than that of the neutrals (which is the ambient temperature). However, as explained above, the increase in Tᵢ is smaller than the increase in Tₑ. Typically, in the bulk plasma, Tᵢ is a few hundred degrees higher than the ambient (e.g., about 350 K to 900 K or 0.03 eV to 0.8 eV).

As described above, the initial transient after plasma ignition rapidly settles to the steady state glow discharge plasma. In the description, we have divided the steady state into three regions, depending on the motion of the ions. Being scattered by collisions, the ions may move with velocities distributed in all directions. At any location, the ion velocity distribution is approximated by a displaced Maxwellian function, which comprises an isotropic part superposed on an anisotropic part. The isotropic part is a Maxwellian with Tᵢ as its temperature, representing the random motion of the ions at that location. The anisotropic part accounts for the ion motion directed perpendicular to the surface that averages to a net directed component of ion velocity, V_{d}, which gives rise to the ion flux at that location. In other words, at any location, the average kinetic energy per ion may be partitioned into a random component equal to 3/2 k_{B}Tᵢ and a directed component equal to ½ Mᵢₒₙ V_{d}², where Mᵢₒₙ is the mass of one ion.

Farthest from the surface is the bulk plasma having the highest densities of ions and free electrons, a negligible net charge and electric field, as well as a high collision rate, mostly with neutrals. As a result, the steady state velocity distributions of ions and free electrons in bulk plasma are almost perfectly isotropic, implying that V_{d} is almost zero and the average kinetic energy per ion may be almost entirely attributed to the random component. Although V_{d} is low in the charge-neutral bulk plasma, there is a slowly moving ion flux (and free electron flux) “drifting” toward the surface. As an ion approaches the vicinity of the substrate, it enters the narrow sheath adjacent to the surface of the substrate. As mentioned above, the plasma sheath is the narrow region of high electric field, where the field is directed to rapidly accelerate the positively charged ion to a high velocity toward the surface.

Prior to entering the sheath, the ions emerging from the bulk plasma pass through the pre-sheath. As mentioned above, the pre-sheath is the region where properties of the steady state plasma transition from their values in bulk plasma to pronouncedly different values at the edge of the sheath. Outside the bulk plasma, the ion and free electron densities reduce progressively toward the surface, with the free electron density dropping faster than the ion density. This results in a net positive charge density profile that starts with a negligibly low value close to the charge-neutral bulk plasma but increases progressively toward the surface through the pre-sheath to reach much higher values in the sheath. The pre-sheath region may be considered to be quasi-neutral, in comparison to the high charge densities inside the sheath. The direction of the electric field increases the ion velocities preferentially toward the surface, thus increasing the anisotropy of the ion distribution function. Indeed, V_{d} starts to increase from almost zero near the bulk plasma and, within a short distance into the pre-sheath, the directed component of kinetic energy (½ Mᵢₒₙ V_{d}²) becomes equal the random component of ion kinetic energy (3/2 k_{B}Tᵢ) and increases further to far exceed 3/2 k_{B}Tᵢ in most of the pre-sheath. In addition, Tᵢ itself increases in the pre-sheath because increasing V_{d} also increases the average kinetic energy of the ions that get scattered in ion-neutral collisions in the pre-sheath region to add to the random motion of ions. However, as explained further below, there may be no further increase in Tᵢ inside the sheath, i.e., Tᵢ reaches its highest value at the edge of the sheath.

The sheath adjacent to the surface of the substrate is formed during the initial transient, when a rapid out-diffusion of free electrons from the plasma to the substrate charges the substrate negatively. The transients settle to where the negative charge of the substrate is balanced by positive space charge in the sheath and an associated electric field profile that attracts ions and repels free electrons. This establishes the steady state comprising a potential profile and ion and free electron fluxes that satisfy the boundary conditions for the surface, for example the applied voltage if the substrate is biased or a net zero current requirement if the substrate is floating. As known to persons skilled in the art, in order to obtain a stable steady state sheath, the average directed velocity of ions entering the sheath needs to exceed a minimum value, referred to as the Bohm velocity. The quasi-neutral pre-sheath (described above) is the region where V_{d} increases till it equals the Bohm velocity at a location defined to be the sheath edge. The pre-sheath being quasi-neutral, most of the positive charge and potential drop occurs the narrow space between the sheath edge and the surface of the substrate, for which the electric field reaches very high values in the sheath.

Consider an ion in the pre-sheath arriving at the sheath edge, where it enters the sheath adjacent above the substrate with a random velocity, Vₒ. Depending on its magnitude and direction, Vₒ may be resolved into a parallel component, Vₓ₀, and a perpendicular component, V_{y0}, (parallel and perpendicular to the surface of the substrate). On average, at this interface (the sheath edge), the parallel and perpendicular components of ion velocity are similar in magnitude. Upon entering the sheath, the ion is accelerated toward the surface by the sheath electric field to acquire high kinetic energy. The sheath being a narrow region of high electric field, the ion is swept across the sheath, typically with a transit time much shorter than the mean free time between collisions. In the absence of collisions, the increase in ion velocity in the sheath is directed parallel to the field, i.e., perpendicular to the surface. In other words, if the velocity with which the ion exits the sheath and impinges on the surface is V₁ then its perpendicular component, V_{y1}, is increased such that V_{y1}>>V_{y0}, but its parallel component, Vₓ₁, is unchanged, i.e., Vₓ₁=Vₓ₀. In addition, since the magnitudes of Vₓ₀ and V_{y0} are similar, generally, V_{y1}>>Vₓ₀.

Note that increasing ion speed in the direction of the field reduces a ratio of the parallel component to the perpendicular component. This, in turn, reduces the ion angle, i.e., brings it closer to the vertical. When the ion enters the sheath at the sheath edge, the ion angle, θₒ, =tan⁻¹ (Vₓ₀/V_{y0}) and, by the time it strikes the surface, the ion angle, θ₁, =tan⁻¹ (Vₓ₁/V_{y1}). Since, Vₓ₁=Vₓ₀ and V_{y1}>>V_{y0}, it follows that θ₁>>θₒ. Furthermore, it can be shown from the inequalities discussed above that the reduction in ion angle (θₒ−θ₁) is larger for an ion that enters the sheath with a bigger angle, θₒ. Thus, the acceleration in the sheath tightens the ion angle distribution, making the ion flux more directional. The sheath electric field may be increased by applying, for example, a negative substrate bias. However, the increased average energy with which the surface is bombarded may have some undesirable effects such as surface damage, surface roughness, and heating.

As mentioned above, reducing the ion incidence angle is important, especially in the etching of high aspect ratio features. The ion angle may be reduced either by increasing the vertical component of ion velocity (V_{y1}) by increasing the sheath electric field with substrate bias or by reducing the horizontal component of ion velocity (Vₓ₀) in the pre-sheath. The kinetic energy associated with Vₓ₀ originates in random collisions; hence, Vₓ₀ may be reduced by reducing the random component of ion kinetic energy, i.e., by reducing Tᵢ. In the absence of randomizing collisions in the sheath (as described above), the random component of ion kinetic energy remains unchanged from that of the ions in the pre-sheath region near the sheath edge. With no further increase in the random component of ion kinetic energy, there is no further increase in Tᵢ inside the sheath, i.e., Tᵢ reaches its highest value at the edge of the sheath.

As discussed above, the ion temperature (Tᵢ) refers to the randomized average energy of ions, randomized by collisions with ions in the charge-neutral bulk plasma and the quasi-neutral pre-sheath. Thus, Tᵢ is the net result of kinetic energy gained by ions through collisions, (e.g., elastic collisions with electrons) and kinetic energy lost by ions through collisions (e.g., collisions with neutrals). An upper limit for Tᵢ may be determined by considering an energy balance condition in the steady state, where ion energy lost by collisions (mostly with neutrals) is balanced, on average, by ion energy gained by collisions (mostly with high energy electrons). This relates the ion temperature, Tᵢ, (which attains its highest value at the sheath edge) to the electron temperature, Tₑ, As known to persons skilled in the art, an approximate mathematical expression using the theory of plasma physics may be derived, wherein Tᵢ ∝Tₑ^{2/3}. From this analysis, it is apparent that a reduction of Tᵢ in the bulk plasma and the pre-sheath may be achieved by reducing the electron temperature there. As explained above, such a condition would improve the ion incidence angle at the substrate being processed by achieving a more collimated ion flux incident on the surface.

Embodiments of the present disclosure use a pulsed DC magnetic field in the chamber to lower Tₑ in the plasma locally above the substrate in order to reduce the spreads in ion angle and energy of the ions in the ion flux used to process the substrate. While it is desirable to reduce Tₑ of the plasma above the substrate in order to achieve a better controlled and highly collimated ion flux incident on the substrate, a high Tₑ may still be desirable for efficiently generating ions and radicals to sustain a desired plasma density in the plasma chamber. Various embodiments of a plasma processing system and method, described in this disclosure, provide the advantage of locally modulating Tₑ during processing, using the pulsed DC magnetic field. As explained in further detail below, a timing of the pulsed DC magnetic field.

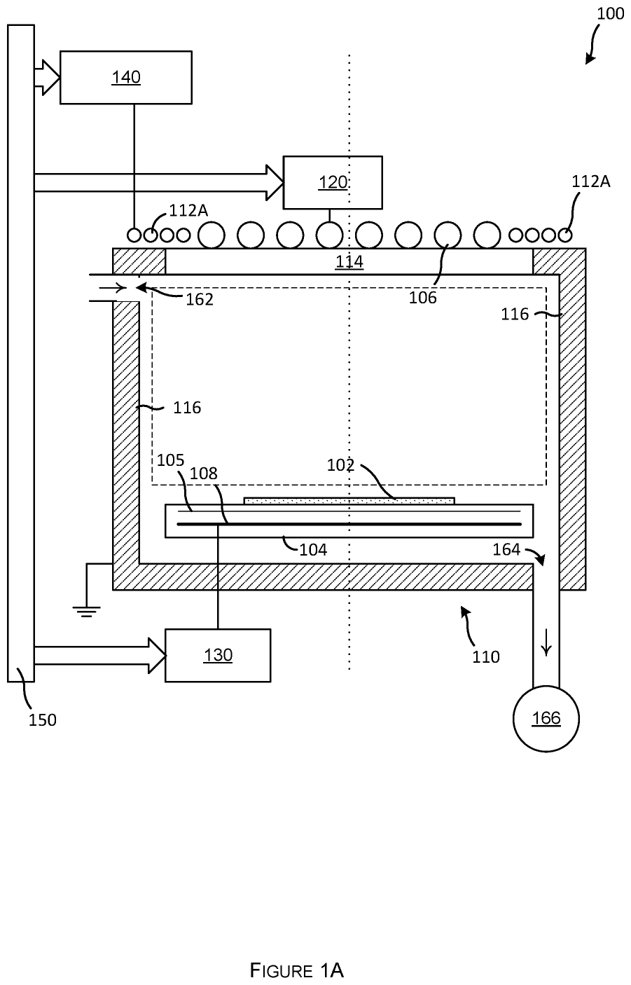

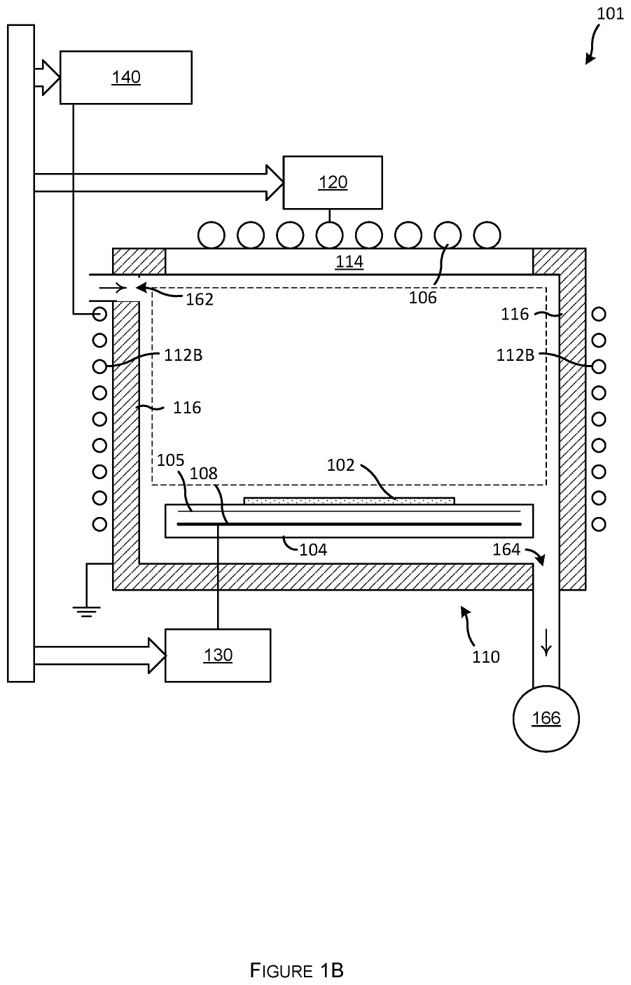

FIG. 1A illustrates a schematic of a plasma processing system 100 for direct plasma processing of a substrate 102 placed over a top insulating surface of a substrate holder 104, shown in a lower portion of a plasma chamber 110. The plasma chamber 110 has a central region around a central axis (indicated by a dotted line in FIG. 1A) passing perpendicularly through a center of the substrate holder 104 within which the substrate 102 is held during processing and a contiguous edge region surrounding the central region. The system 100 is configured to generate a plasma and a pulsed DC magnetic field that modulates an electron temperature (Tₑ) profile of the plasma. The plasma may be generated by ionizing a discharge gas flowing through the chamber 110 with RF source power and pulsed bias power coupled to the gas by a first RF electrode 106 and a second RF electrode 108 of the system 100. The pulsed bias power is obtained from a bias signal, where the bias signal is a periodic series of bias pulses. The pulsed DC magnetic field may be generated by coupling a magnetizing signal that is a periodic series of current pulses to an electromagnet (e.g., a planar electromagnet 112A, illustrated schematically in FIG. 1A). The magnetizing signal is synchronized to be in phase with the bias signal, i.e., in each current pulse, a DC magnetizing current is flowing during the same time a bias voltage waveform is applied in each bias pulse.

The DC magnetic field being a pulsed DC magnetic field, the profile of electron temperature changes with time. A first profile is produced during a time when the DC magnetic field is present and a second profile is produced during a time when the DC magnetic field is absent. An average Tₑ in the central region of the plasma chamber 110 is a first Tₑ (Tₑ₁) for the first profile, and a second Tₑ (Tₑ₂) for the second profile, where Tₑ₂ is greater than or equal to Tₑ₁. The ratio, Tₑ₂/Tₑ₁, increases if the DC magnetizing current is increased.

In the example embodiment in FIG. 1A, the substrate 102 is a semiconductor wafer in an intermediate stage of an IC fabrication flow, and the substrate holder 104 is a wide cylindrical upper portion of a multipurpose pedestal having a hollow stem (not shown) that extends through a floor of the chamber 110 to provide a passage for various connectors coupled to equipment outside the chamber 104, such as electrical wires, pipes to circulate liquid through cooling channels in the substrate holder 104 and an opening to inject gas through the pedestal to grooves on the top surface to cool the backside of the substrate 102. The substrate holder 104 may be operated as an electrostatic chuck (ESC) by placing gripping electrodes 105 within a few millimeters below the top surface to grip a backside of the substrate 102 with DC electric fields that may be generated by coupling DC voltage sources to the gripping electrodes 105 using, for example, wires passing through the stem. Generally, the gripping electrodes 106 comprise a conductive mesh embedded (within a depth of a few millimeters) in the body of the substrate holder 104, which comprises an insulator or a semi-insulating material coated with an insulator (e.g., a ceramic) over which the substrate 102 is placed. In some embodiments, the bottom and side of the substrate holder 104 may be a conductor coated with an insulator (e.g., a ceramic coated refractive metal) for use as an electrode, as described further below.

In some embodiments, a portion of the walls of the chamber 110 may comprise a conductor (e.g., aluminum) coated with an insulator (e.g., yttria), where the conductor is, typically, coupled to a reference potential, commonly referred to as ground.

As mentioned above, RF source power and pulsed bias power may be coupled to the gas in the chamber 110 to generate plasma. An RF source signal may be coupled to the first RF electrode 106 and the bias signal may be coupled to a second RF electrode 108.

In the embodiments described in this disclosure (e.g., system 100 in FIG. 1A), the first RF electrode 106 is an RF antenna or an RF resonator disposed over a dielectric window 114 and configured to couple the RF source power by inducing EM fields in the plasma in the chamber 110. Plasma generated by coupling EM power from an electrode outside the chamber 110 is commonly referred to as inductively coupled plasma (ICP) and the plasma processing system (e.g., the system 100) is said to be configured in an ICP mode.

It is noted that a person skilled in the art may adapt an embodiment having the ICP configuration is used (e.g., system 100 in FIG. 1A) to an embodiment, where the system is configured in a charge coupled plasma (CCP) mode with RF source power coupled to a top electrode exposed to plasma.

The plasma may be sustained by RF power received in an upper portion of the chamber 110 vertically below the first RF electrode 106. However, the plasma extends horizontally to a sidewall 116 and vertically from the ceiling to the substrate holder 104. A dashed rectangle is used in FIG. 1A to indicate the edge of the sheath. The quasi-neutral pre-sheath and the charge-neutral bulk plasma are both in the dashed rectangle.

One advantage of configuring the chamber 110 to generate plasma with power coupled from two independent sources (RF source power and bias power) is that plasma density and the vertical potential and electric field profiles may be adjusted independently. Generally, the RF source signal is used to adjust the plasma density and the bias signal is used to adjust the potential drop across the sheath and the pre-sheath.

A magnetizing signal comprising a periodic series of current pulses may be coupled to the electromagnet (e.g., the planar electromagnet 112A) to generate the pulsed DC magnetic field.

In some embodiments (e.g., the system 100), the first RF electrode 106 is an antenna shaped like a planar coil, positioned over a central portion of a ceiling of the chamber, as illustrated in FIG. 1A. The portion over which the antenna is placed is often referred to as a dielectric window 114, i.e., a dielectric transparent to the RF radiation from the antenna. In the example system 100, the planar coil comprises a single spiraling conductor extending over an area covering the substrate 102. However, it is understood that conductors having various other shapes, such as a resonator shaped like a radiating structure with multiple arms connected to a central ring, may also be used as the first RF electrode 106.

In some embodiments, the chamber 110 has conductive material in a portion of the walls (as mentioned above). That portion excludes the dielectric window 114. For example, an embodiment may have a sidewall 116 of the chamber 110, where the sidewall 116 includes a conductive material (e.g., aluminum) coated with an insulator (e.g., yttria) coupled to ground to form a ground plane around the sides of the plasma chamber 110.

In some embodiments, the second RF electrode 108 is a part of the upper portion of the multipurpose pedestal, which is the substrate holder 104 in the system 100. In the embodiment illustrated in FIG. 1A, the second RF electrode 108 comprises a conductive plate disposed below the gripping electrodes 105 and embedded in the body of the substrate holder 104. In some other embodiment, where the bottom and side of the substrate holder 104 is a conductor coated with an insulator (as mentioned above) the conductive bottom and side of the substrate holder 104 may be used as the second RF electrode 108.

In some embodiments, the electromagnet for generating the pulsed DC magnetic field in the chamber 110 may be a planar electromagnet 112A. The planar electromagnet 112A, illustrated schematically in FIG. 1A, comprises a conductor shaped like a planar coil around a central axis of the chamber 110, where an inner diameter of the coil is greater than a diameter of the substrate 102. As illustrated in FIG. 1A, the conductor is positioned over the ceiling of the chamber 110. In some other embodiment, for example, in a plasma processing system 101, illustrated schematically in FIG. 1B, the electromagnet may be a solenoidal electromagnet 112B. In FIG. 1B, the solenoidal electromagnet 112B comprises a conductor shaped like a helix coiled around the sidewall 116 of the chamber 110, where the coil is disposed outside the chamber 110. Typically, the coil used in an electromagnet (e.g., the planar electromagnet 112A and the solenoidal electromagnet 112B) is constructed as multiple turns of a continuous conductive wire, where each turn is configured to carry equal current. In some embodiments, the coil may coil may comprise more than one continuous wire. In some embodiments, the current in one turn may be different from the current in another turn of the coil. Furthermore, in some embodiments, the electromagnet may be an arrangement of multiple magnets. For example, in some embodiment, the electromagnet may comprise an arrangement of a first electromagnet and a second electromagnet. A first magnetizing signal may be coupled to the first electromagnet and a second magnetizing signal may be coupled to the second electromagnet.

The flow of current, in the planar electromagnet 112A and the solenoidal electromagnet 112B, is axisymmetric around the central axis of the chamber 110, thus the pulsed DC magnetic field produced by the axisymmetric current flow is also axisymmetric. Because of the large inner diameter (larger than the diameter of the substrate 102) of the coil of the planar electromagnet 112A and the coil of the solenoidal electromagnet 112B, the DC magnetizing current flows near the sidewall 116 of the chamber 110. Considering that the strength of a DC magnetic field generated by a current in a wire decreases with increasing distance from the wire, the strength of the pulsed DC magnetic field in the chamber 110 is high near the sidewall 116 and reduces with reducing radial distance from the central axis. Accordingly, on average, the magnetic field strength is low in a central region of the plasma chamber 110 above the substrate 102 relative to the higher average field strength in a contiguous edge region surrounding the central region. Note that the planar electromagnet 112A of the system 100 (in FIG. 1A) as well as the solenoidal electromagnet 112B of the system 101 (in FIG. 1B) are configured to generate a DC magnetic field that is, on average, stronger in the edge region relative to that in the central region, where the substrate 102 is held during processing. A magnetic field may be used to spatially confine charged particles. The confinement is more pronounced for lighter particles, hence, the pulsed DC magnetic field very effective for confining the free electrons. This feature of the pulsed DC magnetic field is utilized in the embodiments described in this disclosure to reduce the average electron temperature, Tₑ, in the central region of the chamber 110, as explained further below.

A DC magnetic field forces mobile charged particles to rotate around magnetic field lines resulting in a spiral motion of free electrons along the field lines of the DC magnetic field in the chamber 110. When a spiraling free electron reaches the sheath then the electric field in the sheath reflect the free electron spiraling back into the bulk plasma. The stronger the DC magnetic field, the smaller is the radius of the spiral. The spiraling motion tends to confine the free electrons along the magnetic field lines. The average values of Tₑ in the chamber 110 change with time because the DC magnetic field is a pulsed DC magnetic field.

The RF source signal, the bias signal, and the magnetizing signal are output by a first electrical circuit 120, a second electrical circuit 130, and a third electrical circuit 140, respectively, as illustrated in FIG. 1A.

The first electrical circuit 120 may comprise an RF oscillator to generate a continuous wave (CW) RF signal and a power amplifier configured to provide sufficient power to the plasma. In a CW RF signal, an RF sinusoidal voltage waveform is applied continuously. In some embodiments, the RF source signal is the CW RF signal. Generally, the first electrical circuit 120 includes an impedance matcher between the power amplifier and the first RF electrode 106 for efficient power transfer from the first electrical circuit 120 to the first RF electrode 106.

While in some embodiments, the RF source signal is a CW RF signal, in some other embodiments the RF source signal is a periodic series of source pulses. Thus, a chopper circuit may be included to allow the first electrical circuit 120 to be configured to output the RF source signal as a CW RF signal or as a periodic series of source pulses. In the example embodiments, i.e. the system 100 in FIG. 1A and the system 101 in FIG. 1B, the configuration of the first electrical circuit 120 may be selected by a controller 150 with a control signal that enables or disables the chopper circuit. The chopper circuit is configured to “chop” a continuous sinusoidal RF voltage waveform to generate a periodic series of RF pulses. In an RF pulse, the sinusoidal RF voltage waveform is applied only during a part of the pulse period. Each source pulse of the periodic series of source pulses is an RF pulse, where an RF source voltage waveform applied only during a source-ON time. Here, the RF source voltage waveform is the RF sinusoidal voltage waveform. Each period of the periodic series of source pulses is a sum of the source-ON time and a source-OFF time. When enabled by the controller 150, the chopper circuit generates the periodic series of source pulses cooperatively with the RF oscillator. The controller 150 is described in further detail below.

The bias signal output by the second electrical circuit 130 is the periodic series of bias pulses (mentioned above), where each period is a sum of a bias-ON time and a bias-OFF time, and for each bias pulse, the bias voltage waveform is applied only during the bias-ON time. The general architecture of the second electrical circuit 130 is similar to that of the first electrical circuit 120 in that both circuits include a signal source, a chopper circuit, a power amplifier, and an impedance matcher. The differences between the first electrical circuit 120 and the second electrical circuit 130 depend on differences between the bias voltage waveform and the RF source voltage waveform.

In some embodiments, the periodic series of bias pulses, which is the bias signal, is a periodic series of DC pulses. In each DC pulse, the bias voltage waveform that is applied during the bias-ON time is a constant DC voltage level. Hence, the periodic series of DC pulses may be generated by “chopping” a continuous constant DC voltage level output from a DC voltage source. The polarity of the DC voltage level is such that the vertically downward component of the electric field in the sheath above the substrate 102 in the chamber 110 is increased.

In some other embodiments, the periodic series of bias pulses is a periodic series of DC-burst pulses. In each DC-burst pulse, the bias voltage waveform applied during the bias-ON time is a plurality of DC pulses. In other words, if a periodic series of DC pulses were sent through another chopper then each DC pulse of the periodic series of DC pulses would be converted to a DC-burst pulse. Hence, a second chopper circuit may be included to allow the second electrical circuit 130 to be configured to output the bias signal as a periodic series of DC pulses or as a periodic series of DC-burst pulses.

As discussed above, one embodiment of the second electrical circuit 130 that can be configured to output the bias signal as a periodic series of DC pulses or as a periodic series of DC-burst pulses comprises a DC voltage source, a first chopper circuit configured to generate a periodic series of DC pulses cooperatively with the DC voltage source, a second chopper circuit configured to generate a periodic series of DC-burst pulses from the periodic series of DC-burst pulses generated by the first chopper circuit, a power amplifier, and an impedance matcher. The second electrical circuit 130 may be configured by the controller 150 with an appropriate control signal that enables the first chopper and the second chopper, depending on which bias voltage waveform is selected to be applied during the bias-ON time.

In yet some other embodiments, the periodic series of bias pulses is a periodic series of RF pulses. In such embodiments, the second electrical circuit 130 comprises an RF oscillator, a chopper circuit, a power amplifier, and an impedance matcher, similar to the first electrical circuit 120, described above.

The magnetizing signal output by the third electrical circuit 140 is a periodic series of current pulses. In order to generate the periodic series of current pulses, the third electrical circuit 140 includes a DC current source and a chopper circuit. The chopper circuit generates current pulses cooperatively with the DC current source, when enabled by a control signal from the controller 150. The controller 150 may synchronize a timing of the control signal to the third electrical circuit 140 with a timing of the control signal to the second electrical circuit 130 to synchronize a timing of the current pulses with a timing of the bias pulses.

The controller 150 may comprise, for example, a processor and a memory. Instructions may be stored in the memory which, when executed in the processor, generate control signals for the first electrical circuit 120 (to select a source signal), the second electrical circuit 130 (to select a bias signal), and the third electrical circuit 140 (to select a magnetizing signal). The control signals from the controller 150 may also be used to synchronize the pulsed signal waveforms generated in the first electrical circuit 120, the second electrical circuit 130, and the third electrical circuit 140 in order to synchronously apply the source signal, the bias signal, the magnetizing signal, and the reference potential to generate the plasma in the chamber 110, as needed for the plasma process.

In the embodiments of plasma processing systems described in this disclosure, prior to coupling the magnetizing signal to the electromagnet (e.g., the planar electromagnet 112A or the solenoidal electromagnet 112B), the magnetizing signal is synchronized with the bias signal to flow the DC magnetizing current only during the bias-ON time. The synchronization ensures that the electromagnet is magnetized during the bias-ON time and demagnetized during the bias-OFF time. Generally, applying bias power increases the potential drop and the vertical electric field in the sheath, thus increasing the vertically directed velocity (V_{y}) with which the ions impinge on the substrate 102, when the bias power is present. Because of the increased kinetic energy of the incident ions, a major portion of the anisotropic etching occurs during the bias-ON time. During the bias-OFF time, the processing progresses with an ion flux having a lower kinetic energy and with radicals diffusing out from the plasma reacting with the substrate 102.

By synchronizing the current pulses with the bias pulses, the magnetic field is turned on only when the bias power is coupled to the plasma in the chamber 110 (i.e., the bias-ON time). This timing of the pulsed DC magnetic field is utilized in the embodiments of this invention to lower Tₑ when anisotropic etching is enhanced with bias power, and allow Tₑ to be returned to its high value after the bias power is removed. Between successive bias pulses (i.e., the bias-OFF time), the substrate 102 remains exposed to the ion flux having a lower kinetic energy and a diffusive radical flux from the plasma, which continue to modify the surface. Returning Tₑ to the higher value with the RF source power restores the plasma density to an initial value. This technique of lowering Tₑ (hence, providing a highly collimated ion flux) during a period of enhanced anisotropic etching along with the raising Tₑ (hence, providing a high plasma density) in at least a part of the time between successive periods of high anisotropic etching is advantageous for etching high aspect ratio features.

During the time the DC magnetizing current is flowing (i.e., the bias-ON time), a magnetic field profile is established in the chamber 110. As mentioned above, the electromagnet (i.e., the electromagnet 112A for system 100 or the electromagnet 112B for system 101) is configured such that the average magnetic field strength is low in a central region of the plasma chamber 110 above the substrate 102 relative to the higher average field strength in a contiguous edge region surrounding the central region. Although the DC magnetic field profile in the chamber 110 of the system 100 (in FIG. 1A) is different from that of the system 101 (in FIG. 1B) because of the different geometries of the planar electromagnet 110A and the solenoidal electromagnet 112B, the DC magnetic field profiles in system 100 as well as system 101 have this characteristic of a stronger field in the edge region relative to the central region. This spatial distribution of the DC magnetic field alters the electron temperature profile such that the average Tₑ, in the central region of the chamber 110 over the substrate 102 is reduced in the presence of the DC magnetic field (Tₑ₁) relative to the average Tₑ, in the central region of the chamber 110 in the absence of the DC magnetic field (Tₑ₂), as explained below.

Being charged particles, the free electrons and ions, moving in random directions in the bulk plasma, experience a force due to the DC magnetic field. The force is directly proportional to a product of the particle velocity, charge, and the DC magnetic field strength. On average, the massive ions move slowly relative to the much lighter free electrons in the bulk plasma. Thus, on average, compared to the free electrons, the ions experience a much weaker force due to the DC magnetic field. Moreover, the acceleration due to a force is inversely proportional to mass. Thus, the impact of the DC magnetic field on ion motion may be ignored.

Consider a free electron in the bulk plasma in the presence of the DC magnetic field. According to the theory of electromagnetism, the force acting on the free electron due to the DC magnetic field (commonly referred to as the Lorentz force) is directed perpendicular to both the direction of its velocity and the direction of the local magnetic field. This causes the free electron to gyrate in a spiral trajectory along a magnetic field line of the DC magnetic field. A radius of the spiral is commonly referred to as the Larmor radius. In general, for a particle having a charge q and mass m, moving at a velocity v in a DC magnetic field of strength B, the Larmor radius, r, is given by r=(mv)/(qB). In other words, each particle is confined within a region that reduces with increasing magnetic field strength and reducing particle mass.

Accordingly, application of the external pulsed DC magnetic field confines the lighter mass free electrons very effectively, and a similar effect on the heavier ions may be ignored. The DC magnetic field does not change the kinetic energy of the free electron. However, as known to persons skilled in the art, the magnetic confinement of the free electrons affects collisions with electrons such that, the transport of electrons via collisions (represented by a diffusion coefficient) and the transport of the random component of electron kinetic energy (represented by a thermal conductivity coefficient), is reduced in the direction along the magnetic field lines (i.e., perpendicular to the direction of the pulsed DC magnetic field). In the example embodiments (system 100 and system 101), the magnetic field lines in the plasma pass roughly from the top to the bottom of the chamber 110, consistent with the configuration of electromagnet 112A in system 100 (see FIG. 1A) and electromagnet 112B in system 101 (see FIG. 1B). Recalling that RF power from the first RF electrode 106 is absorbed by the plasma in an upper portion of the chamber 110 vertically below the first RF electrode 106, it is apparent that the reduced transport of electron kinetic energy reduces Tₑ in the bulk plasma and the per-sheath in the lower portion of the chamber 110, closer to the substrate 102.

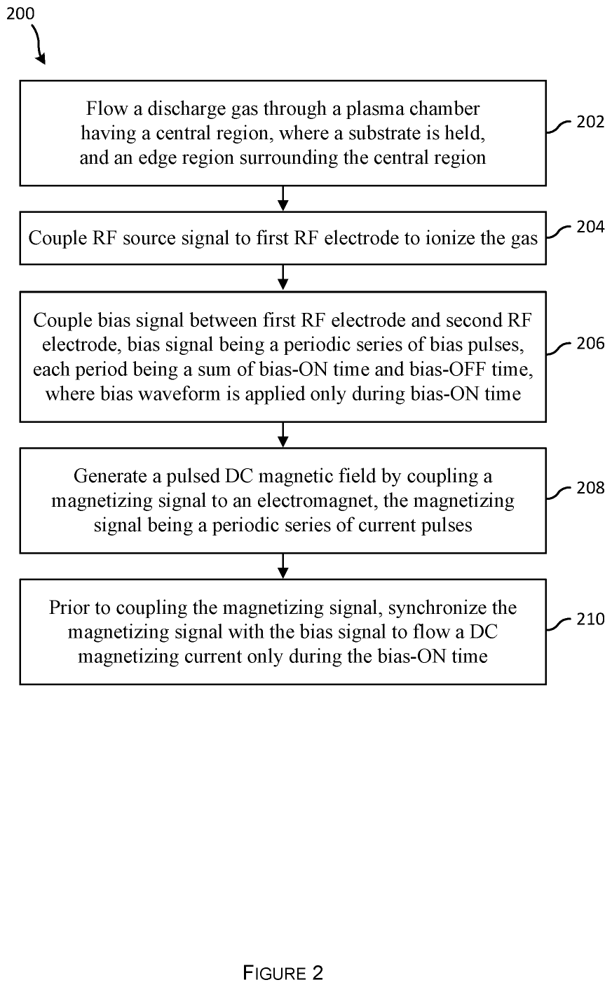

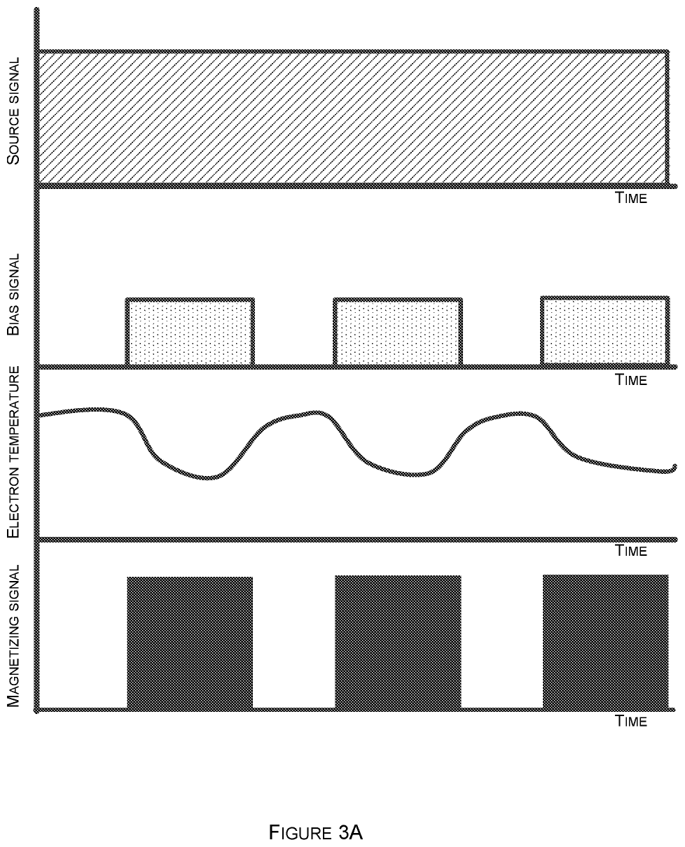

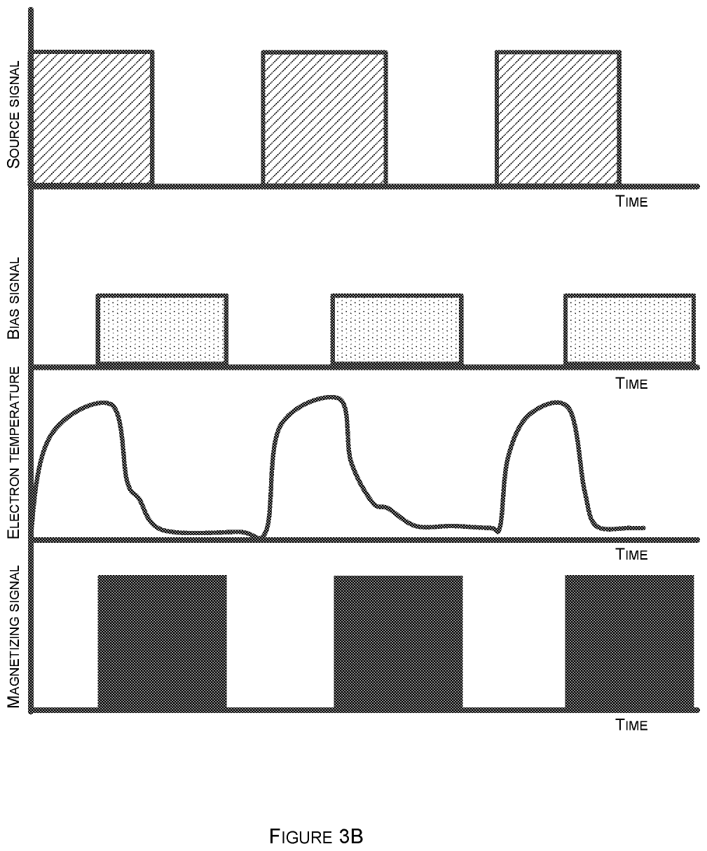

A general method 200 for achieving a time-varying Tₑ in the plasma above the substrate using the pulsed DC magnetic field is described below with reference to a flowchart illustrated in FIG. 2. One embodiment of the method 200, where the RF source signal is a CW RF signal, is described with reference to FIG. 3A. Another embodiment of the method 200, where the RF source signal is a periodic series of source pulses, is described with reference to FIG. 3B.

Referring to FIG. 2, the method 200 for plasma processing a substrate (e.g., substrate 102 in FIG. 1A) comprises generating plasma in a plasma chamber by flowing a discharge gas through the chamber in the chamber (box 202 in FIG. 2) and ionizing the gas (box 204 in FIG. 2) to create a glow discharge. In an example embodiment of a plasma processing system 100, the substrate 102 is held by a substrate holder 104 within a central region of the chamber 110, as illustrated in FIG. 1A.

A controlled gas flow may be maintained using a gas flow system coupled to the chamber 110 of the example embodiment of a plasma processing system 100, illustrated in FIG. 1A. As illustrated in FIG. 1A, the discharge gas is introduced in the chamber 110 through a gas inlet 162 and exits through a gas outlet 164. The gas outlet 164 is coupled to a vacuum pump 166 of the gas flow system. The discharge gas may be a gaseous mixture comprising reactants, diluents, and additives. The gas pumped out through the gas outlet 164 may further include volatile byproducts produced in the chamber 110 during processing. Components of the gas flow system maintains a controlled low pressure in the chamber 110 and controlled flow rates of various gases in the gaseous mixture entering through the gas inlet 162, flowing over the substrate 102, and exiting through the gas outlet 164. In addition to the gas inlet 162, the gas outlet 164, and the vacuum pump 166, the gas flow system may include gas canisters, flow lines, throttle valves, gas flow sensors and controllers, and the like.

The gas may be ionized by coupling an RF source signal to a first RF electrode (e.g., the first RF electrode 106 in FIG. 1A), as indicated in box 204. In the example embodiment of a plasma processing system 100, the planar coil antenna is the first RF electrode 106, as illustrated in FIG. 1A. The RF source signal output by the first electrical circuit 120 may be a CW RF or a periodic series of RF pulses, as described above.

As described above and indicated in box 206 in the flowchart of method 200, illustrated in FIG. 2, the bias signal is applied to the second RF electrode in one of several ways. In the example in FIG. 1A, the second RF electrode 108 is the conductive plate embedded in the body of the substrate holder 104, and as mentioned above, the bias signal from the second electrical circuit 130 has been coupled to the second RF electrode 108 using the switching matrix 160 configured by the controller 150. The bias signal is a periodic series of bias pulses, where a bias voltage waveform is applied only during the bias-ON time. The bias pulses may be DC pulses, DC-burst pulses, or RF pulses, depending on which bias voltage waveform has been selected by the controller 150.

In the method 200, a pulsed DC magnetic field is generated to modulate the electron temperature profile of the steady state plasma. In other words, Tₑ is varied not only with position but also with time by applying the pulsed DC magnetic field. The pulsed DC magnetic field is generated by coupling a magnetizing signal to an electromagnet, where the magnetizing signal is a periodic series of current pulses, as indicated in box 208 in the flowchart of method 200, illustrated in FIG. 2. The example system 100 in FIG. 1A, uses the planar electromagnet 112A, and the example system 101 in FIG. 1B, uses the solenoidal electromagnet 112B.

As mentioned above, a low Tₑ of the plasma above the substrate is desired to reduce the spreads in ion angle and energy distributions, but a high Tₑ is desired to efficiently generate ions and radicals to sustain a desired plasma density. Both desires may be satisfied by a time-varying Tₑ in the plasma above the substrate. Thus, embodiments of the present disclosure modulate Tₑ in the plasma above the substrate to provide a low Tₑ₁ (an average Tₑ in the central region during a time period when the bias power is present) and restore Tₑ to a high Tₑ₂ (an average Tₑ in the central region during a time period when the bias power is absent), as explained above. Hence, as mentioned above, prior to coupling the magnetizing signal, the magnetizing signal is synchronized to be in phase with the bias signal (box 210). In the example system 100 (in FIG. 1A) and the example system 101 (in FIG. 1B), the third electrical circuit 140 is controlled by the controller 150 to generate the current pulses such that the DC magnetizing current is provided only during the bias-ON time, i.e., the same time when the second electrical circuit provides the bias voltage waveform.

FIG. 3A illustrates the waveforms of the source signal, the bias signal, and the magnetizing signal applied in one embodiment of the method 200, where the RF source signal is a CW RF signal. As explained above, the bias signal and the magnetizing signals are in phase, i.e., in each current pulse, a DC magnetizing current is flowing during the same time a bias voltage waveform is applied in each bias pulse. The magnetizing signal being a periodic series of current pulses produces a pulsed DC magnetic field that modulates the average electron temperature in the central region. Being thus modulated by the pulsed DC magnetic field, the average electron temperature in the central region of the chamber changes with time. A graph of electron temperature vs. time, included in FIG. 3A, illustrates the temporal response of this average electron temperature to the applied source, bias, and magnetizing signal waveforms. As explained above, the average electron temperature in the central region of the chamber above the substrate is higher in absence of the DC magnetic field (during the bias-OFF time) and drops in the presence of the DC magnetic field (during the bias-ON time)

FIG. 3B illustrates the waveforms of the source signal, the bias signal, and the magnetizing signal applied in another embodiment of the method 200, where the RF source signal is a periodic series of source pulses, where each source pulse is an RF pulse. As in the embodiment described above with reference to FIG. 3A, the embodiment using the periodic series of source pulses as the RF source signal (illustrated in FIG. 3B) also synchronize the bias pulses of the bias signal to be in phase with the current pulses of the magnetizing signal. The source signal, the bias signal, and the magnetizing signal have the same pulse frequency. However, as illustrated in FIG. 3B, in this example embodiment, the source signal (comprising the periodic series of source pulses) is not synchronized to be in phase with the bias pulses and the current pulses. The temporal response of the average electron temperature in the central region of the chamber 110 over the substrate 102 in this embodiment, where the source signal is the periodic series of RF pulses, as shown in FIG. 3B, is also included in FIG. 3B. It is observed that the average electron temperature in the central region may be reduced by the onset of the magnetic field, similar to the embodiment illustrated in FIG. 3A. However, for the average electron temperature in the central region to be restored to the higher value, it is necessary for the source power to be present.

In some other embodiment, the phase of the source pulses may be selected such that the RF pulses of the source signal are present only during the bias-OFF times, i.e., the pulses of the source signal are “180° out of phase” with the bias pulses. In other words, the source-ON time is coincident with the bias-OFF time and the source-OFF time is coincident with the bias-ON time. Of course, the current pulses of the magnetizing signal, the bias signal being in phase with the magnetizing signal.

It is understood that other set of waveforms may also be used with the method 200, summarized in the flowchart illustrated in FIG. 2.

Example embodiments of the invention are described below. Other embodiments can also be understood from the entirety of the specification as well as the claims filed herein.
Example 1. A method for plasma processing a substrate, where the method includes generating a plasma in a plasma chamber within which the substrate is held during processing, where generating the plasma includes: flowing a discharge gas through the plasma chamber; coupling a radio frequency (RF) source signal to a first RF electrode, where the coupling ionizes the discharge gas; and coupling a bias signal to a second RF electrode, the bias signal being a periodic series of bias pulses, each period having a bias-ON time and a bias-OFF time, where a bias voltage waveform is applied during the bias-ON time; generating a pulsed DC magnetic field in the plasma chamber, by coupling a magnetizing signal to an electromagnet, the magnetizing signal being a periodic series of current pulses; and prior to coupling the magnetizing signal, synchronizing the periodic series of current pulses with the bias signal to flow a DC magnetizing current during the bias-ON time.
Example 2. The method of example 1, where generating the pulsed DC magnetic field further includes: prior to coupling the magnetizing signal, configuring the electromagnet to produce a DC magnetic field profile that generates a first magnetic field profile during the bias-ON time and a second magnetic field profile during the bias-OFF time, the second magnetic field profile being different from the first magnetic field profile.
Example 3. The method of one of examples 1 or 2, where the plasma has an average electron temperature in the plasma chamber to be a first electron temperature during the bias-ON time and a second electron temperature during the bias-OFF time, the second electron temperature being greater than or equal to the first electron temperature, where increasing a magnitude of the DC magnetizing current increases a ratio of the second electron temperature to the first electron temperature.
Example 4. The method of one of examples 1 to 3, where the RF source signal is a periodic series of source pulses, each source pulse being an RF pulse, and each period of the periodic series of source pulses having a source-ON time and a source-OFF time, where an RF sinusoidal voltage waveform is applied during the source-ON time.
Example 5. The method of one of examples 1 to 4, where the source-ON time is coincident with the bias-OFF time and the source-OFF time is coincident with the bias-ON time.
Example 6. The method of one of examples 1 to 5, where the periodic series of bias pulses is a periodic series of DC pulses, where the bias voltage waveform applied during the bias-ON time of each DC pulse is a constant DC voltage level.
Example 7. The method of one of examples 1 to 6, where the periodic series of bias pulses is a periodic series of DC-burst pulses, where the bias voltage waveform applied during the bias-ON time of each DC-burst pulse is a plurality of DC pulses.
Example 8. The method of one of examples 1 to 7, where the periodic series of bias pulses is a periodic series of RF pulses, where the bias voltage waveform applied during the bias-ON time of each RF pulse is an RF sinusoidal voltage waveform.
Example 9. The method of one of examples 1 to 8, further including coupling a conductive portion of walls of the plasma chamber to a reference potential.
Example 10. A system for plasma processing, where the system includes a plasma chamber; a substrate holder configured to hold a substrate in the plasma chamber; a gas flow system configured to flow a discharge gas through the plasma chamber; a first radio frequency (RF) electrode; a second RF electrode, where the first RF electrode and the second RF electrode are configured to cooperatively generate a plasma in the plasma chamber; an electromagnet configured to generate a pulsed DC magnetic field in the plasma chamber, where the pulsed DC magnetic field is configured to modulate an electron temperature profile of the plasma; a first electrical circuit configured to output an RF source signal; a second electrical circuit configured to output a bias signal; a third electrical circuit configured to output a magnetizing signal; and a controller configured to send control signals to the first, second, and third electrical circuits, to adjust and synchronize the RF source signal, the bias signal, and the magnetizing signal.
Example 11. The system of example 10, where the controller includes: a processor; and a memory storing instructions which, when executed in the processor, generate control signals for the first electrical circuit to select a source signal, the second electrical circuit to select a bias signal, the third electrical circuit to select a magnetizing signal, and synchronously apply the source signal, the bias signal, the magnetizing signal, and the reference potential to generate the plasma in the plasma chamber.
Example 12. The system of one of examples 10 or 11, where the first RF electrode is an antenna shaped like a planar coil positioned over a portion of a ceiling of the plasma chamber, the portion being a dielectric window.
Example 13. The system of one of examples 10 to 12, where the electromagnet is a planar electromagnet including a conductor shaped like a planar coil around a central axis passing perpendicularly through a center of the substrate holder, the conductor being positioned over a ceiling of the plasma chamber, where an inner diameter of the planar coil is greater than a diameter of the substrate.
Example 14. The system of one of examples 10 to 13, where the electromagnet is a solenoidal electromagnet including a conductor shaped like a helix coiled around an outer sidewall of the plasma chamber.
Example 15. The system of one of examples 10 to 14, where the electromagnet includes an arrangement of electromagnets, where the arrangement includes: a first electromagnet including a conductor shaped like a first planar coil having a first diameter; and a second electromagnet including a conductor shaped like a second planar coil having a second diameter, the first diameter being larger than the second diameter.
Example 16. The system of one of examples 10 to 15, where the first electrical circuit includes: an RF oscillator configured to generate a continuous wave (CW) RF voltage waveform; a chopper circuit configured to generate a periodic series of RF pulses cooperatively with the RF oscillator, when enabled by a control signal from the controller; a power amplifier; and an impedance matcher.
Example 17. The system of one of examples 10 to 16, where the second electrical circuit includes: an RF oscillator configured to generate a continuous wave (CW) RF voltage waveform; a chopper circuit configured to generate a periodic series of RF pulses cooperatively with the RF oscillator, when enabled by a control signal from the controller; a power amplifier; and an impedance matcher; and where the third electrical circuit includes: a DC current source; and a chopper circuit configured to generate a periodic series of current pulses cooperatively with the DC current source, when enabled by a control signal from the controller.
Example 18. The system of one of examples 10 to 17, where the second electrical circuit includes: a DC voltage source; a first chopper circuit configured to generate a periodic series of DC pulses cooperatively with the DC voltage source, when enabled by a control signal from the controller; a second chopper circuit configured to generate a periodic series of DC-burst pulses from the periodic series of DC-burst pulses generated by the first chopper circuit, when enabled by the control signal from the controller; and a power amplifier; and where the third electrical circuit includes: a DC current source; and a chopper circuit configured to generate a periodic series of current pulses cooperatively with the DC current source, when enabled by a control signal from the controller.
Example 19. A method for plasma processing a substrate, where the method includes flowing a discharge gas through a chamber; coupling a radio frequency (RF) source signal to a first RF electrode; and coupling a bias signal to a second RF electrode, the bias signal being a periodic series of bias pulses, each period being a sum of a bias-ON time and a bias-OFF time, where a bias voltage waveform is applied during the bias-ON time; generating a pulsed DC magnetic field in the chamber, by coupling a magnetizing signal to an electromagnet, the magnetizing signal being a periodic series of current pulses; and prior to coupling the magnetizing signal, synchronizing the periodic series of current pulses with the bias signal to flow a DC magnetizing current during the bias-ON time.
Example 20. The method of example 19, where the electromagnet includes an arrangement of a first electromagnet and a second electromagnet, and where coupling a magnetizing signal to an electromagnet includes simultaneously coupling a first magnetizing signal to the first electromagnet and a second magnetizing signal to the second electromagnet.

What is claimed is:

1. A method for plasma processing a substrate, the method comprising:
generating a plasma in a plasma chamber within which the substrate is held during processing, wherein generating the plasma comprises:
flowing a discharge gas through the plasma chamber;
coupling a radio frequency (RF) source signal to a first RF electrode, wherein the coupling ionizes the discharge gas; and
coupling a bias signal to a second RF electrode, the bias signal being a periodic series of bias pulses, each period having a bias-ON time and a bias-OFF time, wherein a bias voltage waveform is applied during the bias-ON time;
generating a pulsed DC magnetic field in the plasma chamber, by coupling a magnetizing signal to an electromagnet, the magnetizing signal being a periodic series of current pulses; and
prior to coupling the magnetizing signal, synchronizing the periodic series of current pulses with the bias signal to flow a DC magnetizing current during the bias-ON time.

2. The method of claim 1, wherein generating the pulsed DC magnetic field further comprises:
prior to coupling the magnetizing signal, configuring the electromagnet to produce a DC magnetic field profile that generates a first magnetic field profile during the bias-ON time and a second magnetic field profile during the bias-OFF time, the second magnetic field profile being different from the first magnetic field profile.

3. The method of claim 2, wherein the plasma has an average electron temperature in the plasma chamber to be a first electron temperature during the bias-ON time and a second electron temperature during the bias-OFF time, the second electron temperature being greater than or equal to the first electron temperature, wherein increasing a magnitude of the DC magnetizing current increases a ratio of the second electron temperature to the first electron temperature.

4. The method of claim 1, wherein the RF source signal is a periodic series of source pulses, each source pulse being an RF pulse, and each period of the periodic series of source pulses having a source-ON time and a source-OFF time, wherein an RF sinusoidal voltage waveform is applied during the source-ON time.

5. The method of claim 4, wherein the source-ON time is coincident with the bias-OFF time and the source-OFF time is coincident with the bias-ON time.

6. The method of claim 1, wherein the periodic series of bias pulses is a periodic series of DC pulses, wherein the bias voltage waveform applied during the bias-ON time of each DC pulse is a constant DC voltage level.

7. The method of claim 1, wherein the periodic series of bias pulses is a periodic series of DC-burst pulses, wherein the bias voltage waveform applied during the bias-ON time of each DC-burst pulse is a plurality of DC pulses.

8. The method of claim 1, wherein the periodic series of bias pulses is a periodic series of RF pulses, wherein the bias voltage waveform applied during the bias-ON time of each RF pulse is an RF sinusoidal voltage waveform.

9. The method of claim 1, further comprising coupling a conductive portion of walls of the plasma chamber to a reference potential.

10. A system for plasma processing comprising:
a plasma chamber;
a substrate holder configured to hold a substrate in the plasma chamber;
a gas flow system configured to flow a discharge gas through the plasma chamber;
a first radio frequency (RF) electrode;
a second RF electrode, wherein the first RF electrode and the second RF electrode are configured to cooperatively generate a plasma in the plasma chamber;
an electromagnet configured to generate a pulsed DC magnetic field in the plasma chamber, wherein the pulsed DC magnetic field is configured to modulate an electron temperature profile of the plasma;
a first electrical circuit configured to output an RF source signal;
a second electrical circuit configured to output a bias signal;
a third electrical circuit configured to output a magnetizing signal; and
a controller configured to send control signals to the first, second, and third electrical circuits, to adjust and synchronize the RF source signal, the bias signal, and the magnetizing signal.

11. The system of claim 10, wherein the controller comprises:
a processor; and
a memory storing instructions which, when executed in the processor, generate control signals for the first electrical circuit to select a source signal, the second electrical circuit to select a bias signal, the third electrical circuit to select a magnetizing signal, and synchronously apply the source signal, the bias signal, the magnetizing signal, and the reference potential to generate the plasma in the plasma chamber.

12. The system of claim 10, wherein the first RF electrode is an antenna shaped like a planar coil positioned over a portion of a ceiling of the plasma chamber, the portion being a dielectric window.

13. The system of claim 10, wherein the electromagnet is a planar electromagnet comprising a conductor shaped like a planar coil around a central axis passing perpendicularly through a center of the substrate holder, the conductor being positioned over a ceiling of the plasma chamber, wherein an inner diameter of the planar coil is greater than a diameter of the substrate.

14. The system of claim 10, wherein the electromagnet is a solenoidal electromagnet comprising a conductor shaped like a helix coiled around an outer sidewall of the plasma chamber.

15. The system of claim 10, wherein the electromagnet comprises an arrangement of electromagnets, wherein the arrangement comprises:
a first electromagnet comprising a conductor shaped like a first planar coil having a first diameter; and
a second electromagnet comprising a conductor shaped like a second planar coil having a second diameter, the first diameter being larger than the second diameter.

16. The system of claim 10, wherein the first electrical circuit comprises:
an RF oscillator configured to generate a continuous wave (CW) RF voltage waveform;
a chopper circuit configured to generate a periodic series of RF pulses cooperatively with the RF oscillator, when enabled by a control signal from the controller;
a power amplifier; and
an impedance matcher.

17. The system of claim 10,
wherein the second electrical circuit comprises:
an RF oscillator configured to generate a continuous wave (CW) RF voltage waveform;
a chopper circuit configured to generate a periodic series of RF pulses cooperatively with the RF oscillator, when enabled by a control signal from the controller;
a power amplifier; and
an impedance matcher; and
wherein the third electrical circuit comprises:
a DC current source; and
a chopper circuit configured to generate a periodic series of current pulses cooperatively with the DC current source, when enabled by a control signal from the controller.

18. The system of claim 10,
wherein the second electrical circuit comprises:
a DC voltage source;
a first chopper circuit configured to generate a periodic series of DC pulses cooperatively with the DC voltage source, when enabled by a control signal from the controller;
a second chopper circuit configured to generate a periodic series of DC-burst pulses from the periodic series of DC-burst pulses generated by the first chopper circuit, when enabled by the control signal from the controller; and
a power amplifier; and
wherein the third electrical circuit comprises:
a DC current source; and
a chopper circuit configured to generate a periodic series of current pulses cooperatively with the DC current source, when enabled by a control signal from the controller.

19. A method for plasma processing a substrate, the method comprising:
flowing a discharge gas through a chamber;
coupling a radio frequency (RF) source signal to a first RF electrode; and
coupling a bias signal to a second RF electrode, the bias signal being a periodic series of bias pulses, each period being a sum of a bias-ON time and a bias-OFF time, wherein a bias voltage waveform is applied during the bias-ON time;
generating a pulsed DC magnetic field in the chamber, by coupling a magnetizing signal to an electromagnet, the magnetizing signal being a periodic series of current pulses; and
prior to coupling the magnetizing signal, synchronizing the periodic series of current pulses with the bias signal to flow a DC magnetizing current during the bias-ON time.

20. The method of claim 19,
wherein the electromagnet comprises an arrangement of a first electromagnet and a second electromagnet, and
wherein coupling a magnetizing signal to an electromagnet comprises simultaneously coupling a first magnetizing signal to the first electromagnet and a second magnetizing signal to the second electromagnet.
